(19) United States
(12) Patent Application Publication
(10) Pub. No.: US 2005/0159007 A1
(43) Pub. Date: Jul. 21, 2005

(54) Manufacturing method of shallow trench isolation structure

(76) Inventors: Neng-Kuo Chen, Hsinchu City (TW); Teng-Chun Tsai, Hsinchu (TW); Hsiu-Chuan Chu, Hsinchu City (TW); Chih-An Huang, Sindian City (TW)

Correspondence Address: J C PATENTS, INC., 4 VENTURE, SUITE 250, IRVINE, CA, 92618, US

(21) Appl. No.: 10/761,993

(22) Filed: Jan. 21, 2004

(51) Int. Cl. H01L 21/311

(52) U.S. Cl. 438/700

(57) ABSTRACT

A manufacturing method of shallow trench isolation (STI) structure is described. A substrate is provided, wherein a patterned pad oxide layer and a mask layer are formed on the substrate, and at least a trench is formed in the substrate, wherein the trench is formed by exposing a portion of the pad oxide layer and the mask layer. Then, a liner layer on a surface of the trench is formed. A high density plasma chemical vapor deposition (HDP-CVD) process is performed to form an isolation layer on the substrate and over the trench, wherein the trench is at least filled with the isolation layer. The HDP-CVD process includes a first stage process and a second stage process. The bias power of the second stage process is larger than the bias power of the first stage process. Thereafter, the isolation layer over the trench, the mask layer and the pad oxide layer are removed sequentially.

### BACKGROUND OF THE INVENTION

1. Field of the Invention

The present invention generally related to a semiconductor process. More particularly, the present invention relates to a manufacturing method of shallow trench isolation (STI) structure.

2. Related Art of the Invention

In recent years, when the level of integration of the semiconductor circuits and device is getting higher, the isolation between the circuits and the device becomes more important. The isolation layer is provided in the manufacturing process to prevent from the short between the neighboring devices and circuits. The conventionally manufacturing process of the isolation layer includes a localized oxidation isolation (LOCOS) method. The advantage of the LOCOS method is that the cost is low and the performance of the isolation structure between the devices and circuits is good. However, the disadvantages of the LOCOS method includes, at least some issues resulted from the stress and the generation of the bird's beak region around the isolation structure. The generation of the bird's beak region will reduce the integration of the devices and circuits drastically. Therefore, other methods for forming the isolation structure are developed. A most frequent used method is the shallow trench isolation (STI) process.

FIG. 1A to FIG. 1C are cross-sectional views schematically illustrating a process flow of a conventional shallow trench isolation (STI) structure. Referring to FIG. 1A, a substrate 100 having a pad oxide layer 102 and a mask layer 104 is provided. The mask layer 104 is constructed with a silicon nitride layer 101 and a silicon oxide layer 103. A trench 106 is further formed by etching the mask layer 104, the pad oxide layer 102 and the substrate 100.

Referring to FIG. 1B, a thermal oxidation process is performed to form a liner oxide layer 108 on the surface of the trench 106. Thereafter, a silicon oxide isolation layer 110 is deposited on the substrate 100 and over the trench 106, wherein the trench 106 is completely filled with the silicon oxide isolation layer 110.

Then, referring to FIG. 1C, chemical mechanical polishing (CMP) process is performed by using the silicon nitride layer 101 as a polishing stop layer to remove the isolation layer 110 and the silicon oxide layer 103 over the trench 106 and to form the isolation layer 110a. A wet etching process is further performed to remove the mask layer 104 and the pad oxide layer 102.

However, during the process of removing the mask layer 104 and the pad oxide layer 102, the etchant solution used by the wet etching process etches and damages the isolation layer 110a, and a divot 112 around the corner of the trench 106 is generated. Charges are accumulated at the divot 112 and a sub-threshold leakage current of the device of the integrated circuits is generated. Eventually, a kink effect or a gate induced drain leakage (GIDL) effect are generated, and the stability and yield of the device are reduced.

A variety of methods that can solve the issues caused from the divot has been developed recently. For example, one of the method is performed by using a etch-back process to etch and pullback the mask layer to solve the issue. Another method is performed by forming a liner layer to repair the divot generated during the etching of the trench and to release the stress to solve the issue. However, when the integration of the device is getting higher, the size of the device is minimized and the specification of characteristic of the device is tightened, the foregoing methods can not meet the requirement of the process. Thus, how to effectively solve the issue caused by the divot and to prevent the leakage of the current of the device have become an important subject in the 90 nm and sub-90 nm technology of process.

### SUMMARY OF THE INVENTION

Accordingly, one of the purpose of the present invention is to provide a manufacturing method of shallow trench isolation (STI) structure, to preclude the generation of the divot near the corner of the trench during the process.

Another purpose of the present invention is to provide a manufacturing method of shallow trench isolation (STI) structure, wherein the isolation layer for filling the trench is denser.

In order to achieve the above objects and other advantages of the present invention, a manufacturing method of shallow trench isolation (STI) structure is provided. The method includes the following steps. First, a substrate is provided, wherein a patterned pad oxide layer and a mask layer are formed on the substrate, and at least a trench is formed in the substrate, wherein the trench is formed by exposing a portion of the pad oxide layer and the mask layer. Then, a liner layer on a surface of the trench is formed. A high density plasma chemical vapor deposition (HDP-CVD) process is performed to form an isolation layer on the substrate and over the trench, wherein the trench is completely filled with the isolation layer. The high density plasma chemical vapor deposition (HDP-CVD) process includes, for example but not limited to, a first stage process and a second stage process. The bias power of the second stage process is higher than the bias power of the first stage process, and the deposition to etching ratio of the second stage process is less than the deposition to etching ratio of the first stage process. Thereafter, the isolation layer over the trench, the mask layer and the pad oxide layer are removed sequentially.

In order to achieve another objects and other advantages of the present invention, a manufacturing method of shallow trench isolation (STI) structure is provided. The method includes the following steps. First, a substrate is provided, wherein a patterned pad oxide layer and a mask layer are formed on the substrate, and at least a trench is formed in the substrate, wherein the trench is formed by exposing a portion of the pad oxide layer and the mask layer. An etch-back process is further performed to the mask layer to etch and pull back the mask layer. Then, a liner layer on a surface of the trench is formed. A high density plasma chemical vapor deposition (HDP-CVD) process is performed to form an isolation layer on the substrate and over the trench, wherein the trench is completely filled with the isolation layer. The high density plasma chemical vapor deposition (HDP-CVD) process includes, for example but not limited to, a first stage process and a second stage process. The bias power of the second stage process is higher than the bias power of the first stage process, and the deposition to etching ratio of the second stage process is less than the deposition to etching ratio of the first stage process. Thereafter, the isolation layer over the trench, the mask layer and the pad oxide layer are removed sequentially.

Accordingly, since in the manufacturing method of shallow trench isolation (STI) structure of the invention, the bias power of the second stage process is larger than that of the first stage process, and/or the deposition to etching ratio of the second stage process is less than that of the first stage process, the isolation material deposited by the second stage process is denser. Moreover, since the isolation layer that fills the trench is denser, the divot generated around the corner of the trench during the removing of the mask layer and the pad oxide layer is mitigated, or eliminated.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are cross-sectional views schematically illustrating a process flow of a conventional shallow trench isolation (STI) structure.

FIG. 2A to FIG. 2F are cross-sectional views schematically illustrating a process flow of a shallow trench isolation (STI) structure according to a preferred embodiment of the invention.

FIG. 3 is a diagram illustrating the measurement results of the junction leakage current of the wafers made from the method of the invention and prior art under a variety of bias power of radio frequency (RF) of the deposition process.

FIG. 4A and FIG. 4B are pictures of the shallow trench isolation (STI) structure taken from a scanning electron microscope (SEM), wherein FIG. 4A is a picture of the shallow trench isolation (STI) structure fabricated according to the method of prior art under normal bias power, and FIG. 4B is a picture of the shallow trench isolation (STI) structure fabricated according to the method of the invention under a high bias power.

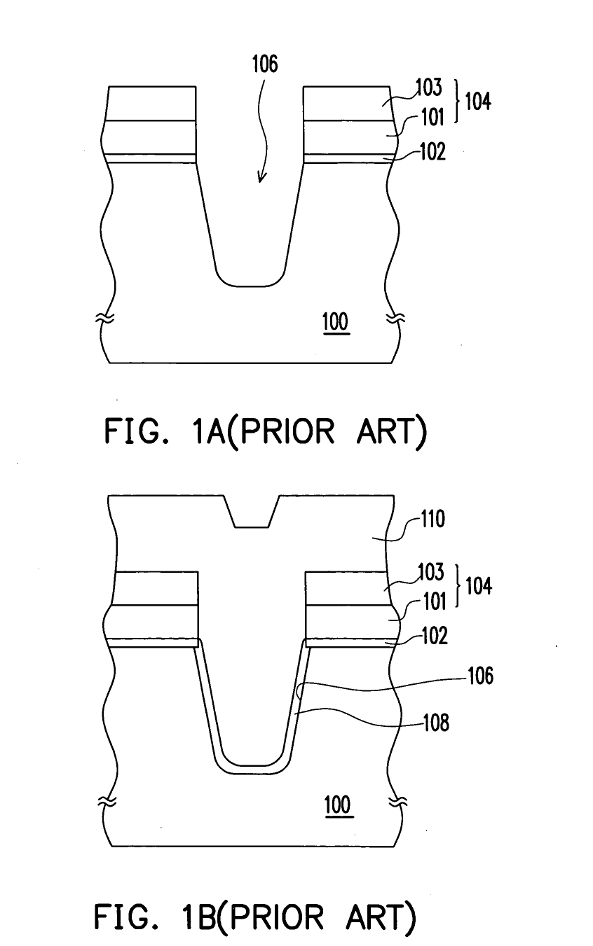

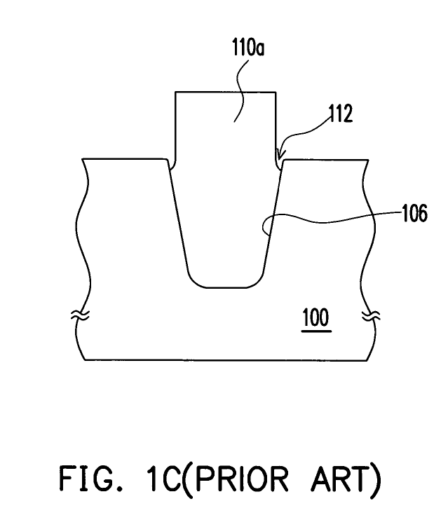

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

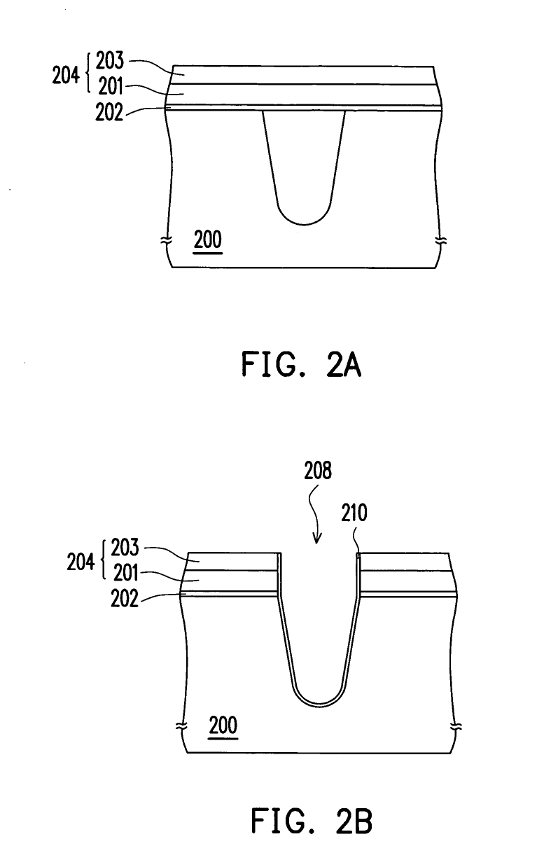

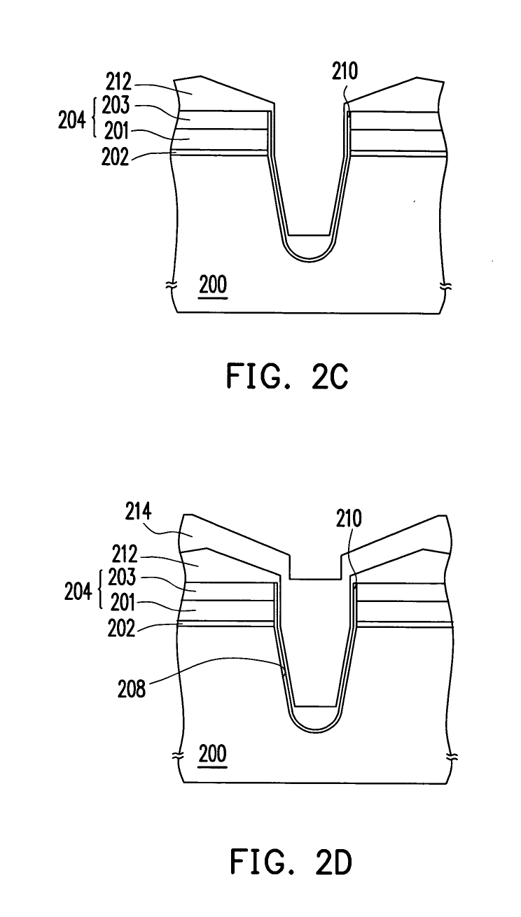

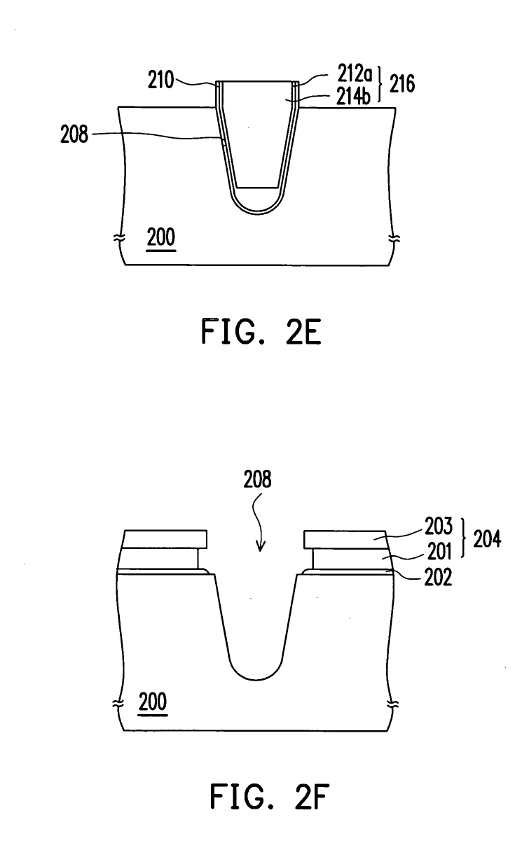

FIG. 2A to FIG. 2F are cross-sectional views schematically illustrating a process flow of a shallow trench isolation (STI) structure according to a preferred embodiment of the invention.

Referring to FIG. 2A, the manufacturing method of shallow trench isolation (STI) structure of the invention includes, for example but not limited to, providing a substrate 200. A pad oxide layer 202 and a mask layer 204 are formed on the substrate 200 sequentially. The material of the pad oxide layer 202 includes, for example but not limited to, silicon oxide. The method of forming the pad oxide layer 202 includes, for example but not limited to, a thermal oxidation process. Moreover, in the present embodiment, the mask layer 204 is constructed by a bottom layer, e.g., a silicon nitride layer 201 and a top layer, e.g., a silicon oxide layer 203. The method of forming the silicon nitride layer 201 includes, for example but not limited to, a chemical vapor deposition (CVD) process. Moreover, The method of forming the silicon oxide layer 203 includes, for example but not limited to, a chemical vapor deposition (CVD) process by using tetraethyl ortho-silicate (TEOS). In addition, in another preferred embodiment, the mask layer 204 is only constructed by, for example but not limited to, the silicon nitride layer 201.

Continuing to FIG. 2B, the silicon oxide layer 203, the silicon nitride layer 201 and the pad oxide layer 202 are patterned in order to expose the trench structure in the substrate 200. Then, the trench 208 is formed by etching the substrate 200 using the patterned silicon oxide layer 203, the silicon nitride layer 201 and the pad oxide layer 202 as an etching mask.

Thereafter, referring to FIG. 2B, a liner layer 210 is formed on the surface of the trench 208. The material of the liner layer 210 includes, for example but not limited to, a silicon oxide. The method of forming the liner layer 210 includes, for example but not limited to, a thermal oxidation process. The advantage of forming the liner layer 210 is that the corner of the trench 208 is rounded, and thus the stress is released. Moreover, the forming of the liner layer 210 can also repair the damage of the substrate 200 caused during the aforementioned etching process of the trench 208.

Thereafter, referring to FIG. 2C, a first stage process of the high density plasma chemical vapor deposition (HDP-CVD) process is performed to form the isolation protection layer 212, and isolation protection layer 212 covers the structure formed on the substrate 200. The material of the isolation protection layer 212 includes, for example but not limited to, silicon oxide. The bias power of radio frequency (RF) of the high density plasma chemical vapor deposition (HDP-CVD) process is, for example but not limited to, less than 2500 W, and is preferable in a range of about 900 W to about 2500 W. Moreover, the deposition to etching ratio is, for example but not limited to, larger than 10, and is preferable in a range of about 10 to about 20.

It is noted that the bias power of radio frequency used by the high density plasma chemical vapor deposition (HDP-CVD) process is used to control the direction of the plasma in providing the bombardment. Therefore, the high density plasma chemical vapor deposition (HDP-CVD) process can provide the effect of deposition and etching. Moreover, the isolation protection layer 212 formed by the high density plasma chemical vapor deposition (HDP-CVD) process can cover the structure formed on the substrate 200. Thus, the damage of the structure caused by the successive second stage process of the high density plasma chemical vapor deposition (HDP-CVD) process can be prevented.

Referring to FIG. 2D, the second stage process of the high density plasma chemical vapor deposition (HDP-CVD) process is performed to form the isolation layer 214 on the substrate 200 and over the trench 208, wherein the trench 208 is completely filled with the isolation layer 214. The material of the isolation layer 214 is, for example, the same as the isolation protection layer 212 and includes, for example but not limited to, silicon oxide. The bias power of radio frequency (RF) of the high density plasma chemical vapor deposition (HDP-CVD) process is, for example but not limited to, larger than 2500 W, and is preferable in a range of about 2500 W to about 3300 W. Moreover, the deposition to etching ratio is, for example but not limited to, less than 10, and is preferable in a range of about 5 to about 10.

Likewise, the bias power of radio frequency used by the high density plasma chemical vapor deposition (HDP-CVD) process is used to control the direction of the plasma to providing the bombardment. Therefore, the high density plasma chemical vapor deposition (HDP-CVD) process can provide the effect of deposition and etching. Moreover, since the bias power of radio frequency of the second stage process is larger than that of the first stage process, and the deposition to etching ratio of the second stage process is lower than that of the first stage process, the bombardment effect of the second stage process is larger than that of the first stage process, and the isolation material deposited by the second stage process is denser. In addition, although the deposition to etching ratio of the second stage process is lower than that of the first stage process, the decrease of the ratio is due to the increase of the etching rate. Thus, the deposition rate is not affected. Accordingly, the throughput of the process will not be reduced.

Thereafter, referring to FIG. 2E, the isolation layer 214 and the isolation protection layer 212 over the trench 208 is removed. In the present embodiment, the foregoing removing step further includes removing the silicon oxide layer 203. The method of performing the removing step includes, for example but not limited to, a chemical mechanical polishing (CMP) process by using the silicon nitride layer 201 as a polishing stop layer. After the removing step, an isolation gapfill layer 216 includes an isolation layer 214a and an isolation protection layer 212a.

Referring to FIG. 2E, the silicon nitride layer 201 is removed. The removing method includes, for example but not limited to, using a hot phosphoric acid as an etchant to perform a wet etching process. Then, the pad oxide layer 202 is removed. The removing method includes, for example but not limited to, using a hydrogen fluoride acid (HF) as an etchant to perform a wet etching process. It is noted that, since the isolation layer 214 (i.e., the isolation gapfill layer 216) is denser, the divot generated on the corner of the trench 208 during the removing of the silicon nitride layer 201 and the pad oxide layer 202 is mitigate or eliminated.

Moreover, in another preferred embodiment, after the trench 208 is formed (as shown in FIG. 2A), and before the liner layer 210 is formed (as shown in FIG. 2B), the method further includes performing an etch-back process to the mask layer 204 to obtain the structure as shown in FIG. 2F. The etch-back process further etches and pulls back the sides of the mask layer 204 and the pad oxide layer 202. The etch-back process is mainly provided for removing the silicon nitride layer 201 at the side wall of the trench 208. However, since the etchant etches the silicon oxide layer 203 and the pad oxide layer 202 at the same time, the silicon oxide layer 203, silicon nitride layer 201 and pad oxide layer 202 are etched also, and thus the surface of the substrate 200 at the corner of the trench 208 is exposed. Hence, the successive gapfill process and the corner rounding of the trench 208 can be performed much easily. After the etch-back process, the process as illustrated in FIG. 2C to FIG. 2E are performed successively to achieve the shallow trench isolation (STI) structure.

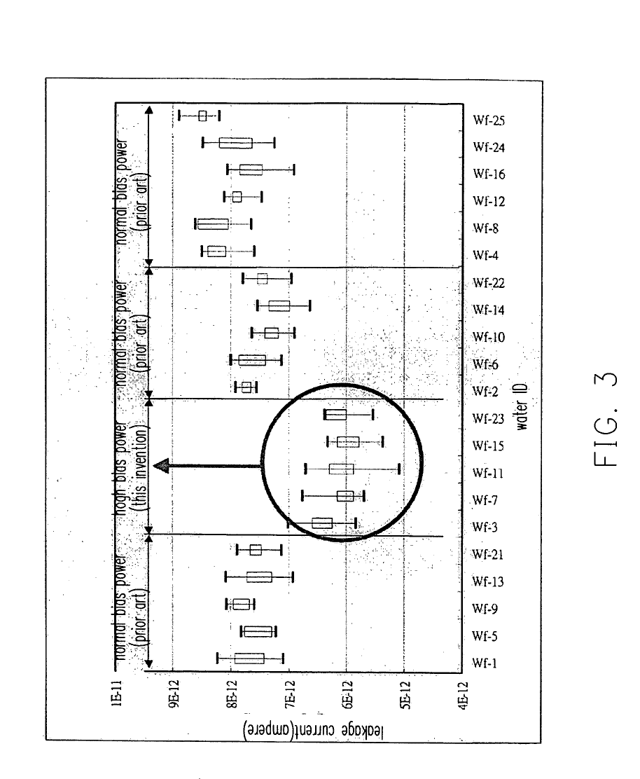

Hereinafter, the junction leakage current of the samples made from the method of the invention and prior art are measured under a variety of bias power of radio frequency, of the deposition process and the result is shown, for example, in FIG. 3. The measurement results are described in the following. It is noted that the method of the invention can improve the issue caused from the divot around the corner of the trench and can reduce the leakage current of the device.

FIG. 3 is a diagram illustrating the measurement results of the junction leakage current of the wafers fabricated under a variety of bias power of radio frequency (RF) for deposition according to the method of the invention and the prior art. The horizontal axis represents the wafer identity (ID) that is measured, and the vertical axis represents the junction leakage current (in Ampere). In FIG. 3, the measurement results are separated into four region. Marked from the left to the right, (1) the first region is the measurement results of the wafers made from the method of prior art under normal bias power of radio frequency, (2) the second region is the measurement results of the wafers made from the method of the invention under high bias power of radio frequency, (3) the third region is the measurement results of the wafers made from the method of prior art under normal bias power of radio frequency, and (4) the fourth region is the measurement results of the wafers made from the method of prior art under normal bias power of radio frequency.

As shown in FIG. 3, it is noted that the leakage current in region (2) is less than that in the other regions. Therefore, the junction leakage current of the wafers made from the method of the invention under the high bias power is less than that made from the method of prior art under the normal bias power. Accordingly, the method of the invention can enhance the density of the deposited isolation layer and can reduce the leakage current of the device.

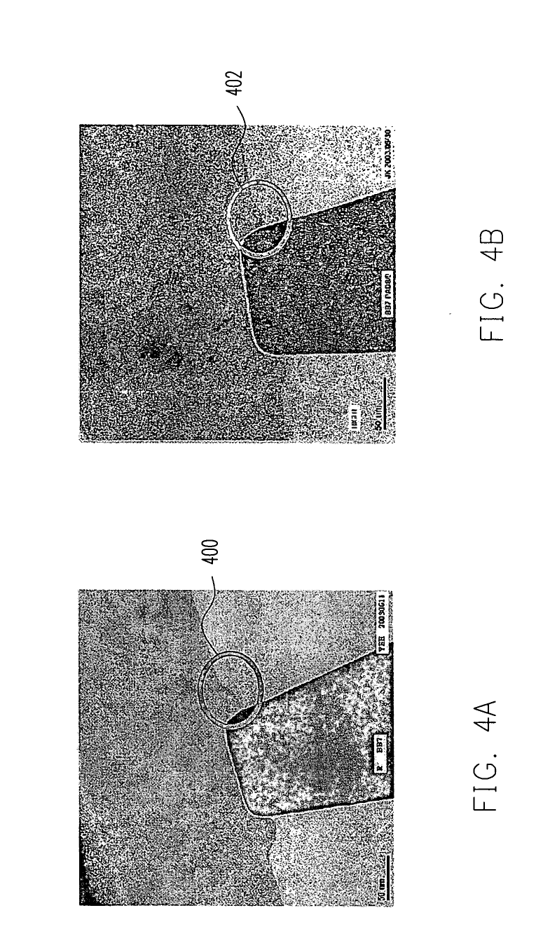

Moreover, the shallow trench isolation (STI) structure after the mask layer and the pad oxide layer are removed is measured by the scanning electron microscope (SEM) and the picture is shown in FIG. 4A and FIG. 4B. FIG. 4A is a picture of the shallow trench isolation (STI) structure fabricated according to the prior art method under a normal bias power, and FIG. 4B is a picture of the shallow trench isolation (STI) structure fabricated according to the method of the invention under high bias power.

As shown in FIG. 4A and FIG. 4B, it is noted that the shallow trench isolation (STI) structure fabricated according to the method of the invention the divot 402 formed at the corner of the trench under a high bias power of radio frequency is better than the divot 400 since the depth of the divot of the invention is shallower that that of the prior art. In an embodiment of the invention, the depth of the divot 400 and 402 at the corner of the trench is measured. As a result, the depth of the divot 400 around the corner of the shallow trench isolation (STI) structure fabricated according to the method of prior art under a normal bias power of radio frequency is about 16.07 nm. However, the depth of the divot 402 around the corner of the shallow trench isolation (STI) structure fabricated according to the method of the invention under high bias power of radio frequency is only about 7.3 nm. Thus, the method of the invention can improve the issues resulted from the divot formed at the corner of the trench.

Accordingly, the advantages of the invention at least includes the following:

Since in the manufacturing method of shallow trench isolation (STI) structure of the invention, the bias power of the second stage process is higher than that of the first stage process, and/or the deposition to etching ratio of the second stage process is lower than that of the first stage process, the isolation material deposited by the second stage process is denser. Moreover, since the isolation layer is denser, the divot generated around the corner of the trench during the removing of the mask layer and the pad oxide layer can be mitigated, or be eliminated.

The high density plasma chemical vapor deposition (HDP-CVD) process of the invention can not only provide a denser isolation layer, it also can improve the gapfilling of the high density plasma chemical vapor deposition (HDP-CVD) process.

The method of the invention does not only be limited in the application of a two stage process of a high density plasma chemical vapor deposition (HDP-CVD) process, it can also be applied in an at least two stage process of a high density plasma chemical vapor deposition (HDP-CVD) process. In other words, when the last stage process of the at least two stage process of a high density plasma chemical vapor deposition (HDP-CVD) process applies the method of the second stage process of the invention, a denser isolation layer is resulted.

In the high density plasma chemical vapor deposition (HDP-CVD) process of the invention, although the deposition to etching ratio of the second stage process is lower than that of the first stage process the deposition rate is not affected since the decrease of the ratio is due to the increase of the etching rate. Accordingly, the throughput of the process will not be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A manufacturing method of a shallow trench isolation (STI) structure, the method comprising:
providing a substrate, wherein a patterned pad oxide layer and a mask layer are formed on the substrate, and at least a trench is formed in the substrate, wherein the trench is formed by exposing a portion of the pad oxide layer and the mask layer;
forming a liner layer on a surface of the trench;
performing a high density plasma chemical vapor deposition (HDP-CVD) process to form an isolation layer on the substrate and over the trench, wherein the trench is completely filled with the isolation layer, wherein the high density plasma chemical vapor deposition (HDP-CVD) process comprises a first stage process and a second stage process, and a bias power of the second stage process is higher than a bias power of the first stage process, and a deposition to etching ratio of the second stage process is lower than a deposition to etching ratio of the first stage process;
removing the isolation layer over the trench;
removing the mask layer; and
removing the pad oxide layer.

2. The manufacturing method of shallow trench isolation (STI) structure of claim 1, wherein the bias power of the first stage process is in a range of about 900 W to about 2500 W.

3. The manufacturing method of shallow trench isolation (STI) structure of claim 1, wherein the bias power of the second stage process is in a range of about 2500 W to about 3300 W.

4. The manufacturing method of shallow trench isolation (STI) structure of claim 1, wherein the deposition to etching ratio of the first stage process is in a range of about 10 to about 20.

5. The manufacturing method of shallow trench isolation (STI) structure of claim 1, wherein the deposition to etching ratio of the second stage process is in a range of about 5 to about 10.

6. The manufacturing method of shallow trench isolation (STI) structure of claim 1, wherein the bias power of the second stage process is in a range of about 2500 W to about 3300 W, and the deposition to etching ratio of the second stage process is in a range of about 5 to about 10.

7. The manufacturing method of shallow trench isolation (STI) structure of claim 1, wherein a material of the isolation layer comprises silicon oxide.

8. The manufacturing method of shallow trench isolation (STI) structure of claim 1, wherein the mask layer comprises a bottom silicon nitride layer on the bottom and a top silicon oxide layer.

9. The manufacturing method of shallow trench isolation (STI) structure of claim 8, wherein the step of removing the isolation layer over the trench further comprises a step of removing the silicon oxide layer.

10. A manufacturing method of shallow trench isolation (STI) structure, the method comprising:
providing a substrate, wherein a patterned pad oxide layer and a mask layer are formed on the substrate, and at least a trench is formed in the substrate, wherein the trench is formed by exposing a portion of the pad oxide layer and the mask layer;
performing an etch-back process to the mask layer to pull back the mask layer;
forming a liner layer on a surface of the trench;
performing a high density plasma chemical vapor deposition (HDP-CVD) process to form an isolation layer on the substrate and over the trench, wherein the trench is completely filled with the isolation layer, wherein the high density plasma chemical vapor deposition (HDP-CVD) process comprise a first stage process and a second stage process, a bias power of the second stage process is higher than a bias power of the first stage process, and a deposition to etching ratio of the second stage process is lower than a deposition to etching ratio of the first stage process;
removing the isolation layer over the trench;
removing the mask layer; and
removing the pad oxide layer.

11. The manufacturing method of shallow trench isolation (STI) structure of claim 10, wherein the bias power of the first stage process is in a range of about 900 W to about 2500 W.

12. The manufacturing method of shallow trench isolation (STI) structure of claim 10, wherein the bias power of the second stage process is in a range of about 2500 W to about 3300 W.

13. The manufacturing method of shallow trench isolation (STI) structure of claim 10, wherein the deposition to etching ratio of the first stage process is in a range of about 10 to about 20.

14. The manufacturing method of shallow trench isolation (STI) structure of claim 10, wherein the deposition to etching ratio of the second stage process is in a range of about 5 to about 10.

15. The manufacturing method of shallow trench isolation (STI) structure of claim 10, wherein the bias power of the second stage process is in a range of about 2500 W to about 3300 W, and the deposition to etching ratio of the second stage process is in a range of about 5 to about 10.

16. The manufacturing method of shallow trench isolation (STI) structure of claim 10, wherein a material of the isolation layer comprises silicon oxide.

17. The manufacturing method of shallow trench isolation (STI) structure of claim 10, wherein the mask layer comprises a bottom silicon nitride layer and a top silicon oxide layer.

18. The manufacturing method of shallow trench isolation (STI) structure of claim 17, wherein the step of removing the isolation layer over the trench further comprises a step of removing the silicon oxide layer.
